(19) United States
(12) Patent Application Publication
(10) Pub. No.: US 2007/0291939 A1
(43) Pub. Date: Dec. 20, 2007

(54) Method and system for transmission of uncompressed video over wireless channels

(75) Inventors: Harkirat Singh, Santa Clara, CA (US); Huai-Rong Shao, San Jose, CA (US); Chiu Ngo, San Francisco, CA (US)

Correspondence Address: Kenneth L. Sherman, Esq.;Myers Dawes Andras & Sherman, LLP, 11th Floor, 19900 MacArthur Blvd., Irvine, CA, 92612, US

(73) Assignee: Samsung Electronics Co., Ltd., Suwon City (KR)

(21) Appl. No.: 11/706,897

(22) Filed: Feb. 13, 2007

Related U.S. Application Data
(60) Provisional application No. 60/774,150, filed on Feb. 15, 2006.

(51) Int. Cl. H04N 7/167; H03M 13/47

(52) U.S. Cl. 380/210; 714/752

(57) ABSTRACT

A method and a system for transmitting uncompressed video over a communication medium such as wireless channel, is provided. For each pixel of video information, at least one portion of the pixel information is encrypted to generate encrypted data, and then the encrypted data is encoded for transmission error recovery. The encrypted and encoded data along with the remaining portion of the pixel information is transmitted over the communication medium.

### RELATED APPLICATION

This application claims priority from U.S. Provisional Patent Application Ser. No. 60/774,150, filed on Feb. 15, 2006, incorporated herein by reference.

### FIELD OF THE INVENTION

The present invention relates to wireless communications and in particular, to transmission of uncompressed video over wireless channels.

### BACKGROUND OF THE INVENTION

With the proliferation of high quality video, an increasing number of electronics devices (e.g., consumer electronics devices) utilize high-definition (HD) video. Conventionally, most devices compress the HD video, which can be around 1 Gbps (gigabits per second) in bandwidth, to a fraction of its size to allow for transmission between devices. However, with each compression and subsequent decompression of the video, some video information can be lost and the picture quality is degraded.

The High-Definition Multimedia Interface (HDMI) specification defines an interface for uncompressed HD transmission between devices through HDMI cables (wired links). Three separate channels are used to transmit three pixel components (e.g., R, B, G). For each channel, pixels are transmitted in a pixel-by-pixel order for each video line and line-by-line for each video frame or field. The HDMI provides pixel-repetition functionality which repeats each pixel one or multiple times. Copies of each pixel directly follow the original pixel during the transmission at each pixel component channel.

Existing Wireless Local Area Networks (WLANs) and similar technologies do not have the bandwidth needed to carry uncompressed HD video, such as providing an air interface to transmit uncompressed video over a 60 GHz bandwidth. Further, existing networks can suffer from interference issues when several devices are connected, leading to video signal degradation.

### BRIEF SUMMARY OF THE INVENTION

The present invention provides a method and a system for transmitting uncompressed video over a communication medium, such as a wireless channel, by inputting video information including video pixels, for each video pixel, encrypting at least one portion of the pixel information to generate encrypted data, and encoding the encrypted data for transmission error recovery, and transmitting the encrypted and encoded data along with the remaining portion of the pixel information, over the communication medium.

The encrypted and encoded video data is transmitted from a transmitter to a receiver, which performs the reverse processes to reconstruct the uncompressed video. Bits at higher video importance levels have a more significant contribution in terms of video information than bits at lower video importance levels. As such, important bits are provided with stronger encryption and protection for transmission and error recovery, relative to less important bits.

In one implementation, perceptual encryption (PE) is utilized such that the bit-plane of a pixel component of K bits is partitioned into M most significant bits (MSBs) and L least significant bits (LSBs). The MSBs have higher importance levels than LSBs. The M MSBs are encrypted, whereas the L LSBs are left as is. Then, FEC encoding is applied to protect encrypted MSB bits which carry more valuable information than the LSBs.

Using perceptual encryption reduces computation time of an encryption algorithm and PE does not compromise the confidentiality of the uncompressed HD video. Further, FEC encoding protects relatively important information of a pixel component by providing them with stronger transmission error recovery encoding.

These and other embodiments, aspects and advantages of the present invention will become understood with reference to the following description, appended claims and accompanying figures.

### BRIEF DESCRIPTION OF THE DRAWINGS

FIG. 1 shows example architecture for encrypting and encoding uncompressed video for wireless transmission, according to an embodiment of the present invention.

FIG. 2 shows a functional block diagram of a communication system implementing the architecture of FIG. 1, according to an embodiment of the present invention.

FIGS. 3A-B show examples of conventional selective bit-plane encryption including encrypted MSBs and encrypted LSBs, respectively.

FIG. 4 shows an example perceptual encryption scheme for encrypting uncompressed video, according to an embodiment of the present invention.

FIG. 5 shows another example of functional architecture for encrypting and encoding uncompressed video for wireless transmission, according to an embodiment of the present invention.

FIG. 6 shows an example flowchart of a process for PE and FEC for wireless transmission, according to an embodiment of the present invention.

FIG. 7 illustrates a conventional High-bandwidth Digital Content Protection (HDCP) encryption scheme.

FIG. 8 illustrates an example of PE, wherein 50% of the bits are encrypted and the other 50% of the bits are left as plain text, according to an embodiment of the present invention.

FIG. 9 illustrates an example of PE and FEC processing, according to an embodiment of the present invention.

### DETAILED DESCRIPTION OF THE INVENTION

The present invention provides a method and a system for transmitting uncompressed video over a wireless channel with sufficient bandwidth to support e.g. uncompressed HD (high definition) 1080p video, wherein limited re-transmissions are possible.

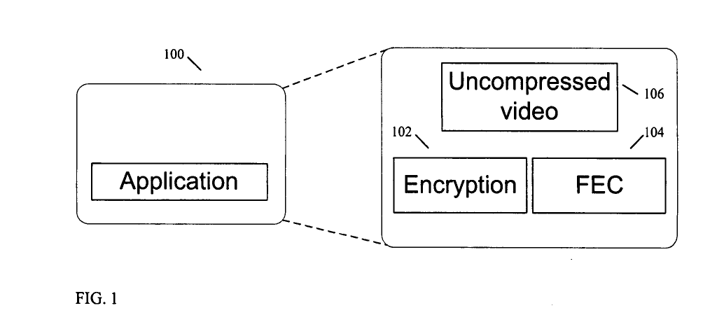

FIG. 1 shows example architecture of an application 100 for transmission of uncompressed video, according to the present invention. Since a wireless channel is susceptible to both eavesdropping and bit error loss, the application 100 applies both FEC 104 and encryption 102 to uncompressed video 106, for transmission over a wireless network. Application of FEC combats bit error losses, and application of encryption combats eavesdropping.

As the uncompressed video 106 can be quite large, and real-time encryption is computation time intensive, the present invention provides PE 102 for reducing the computation overhead.

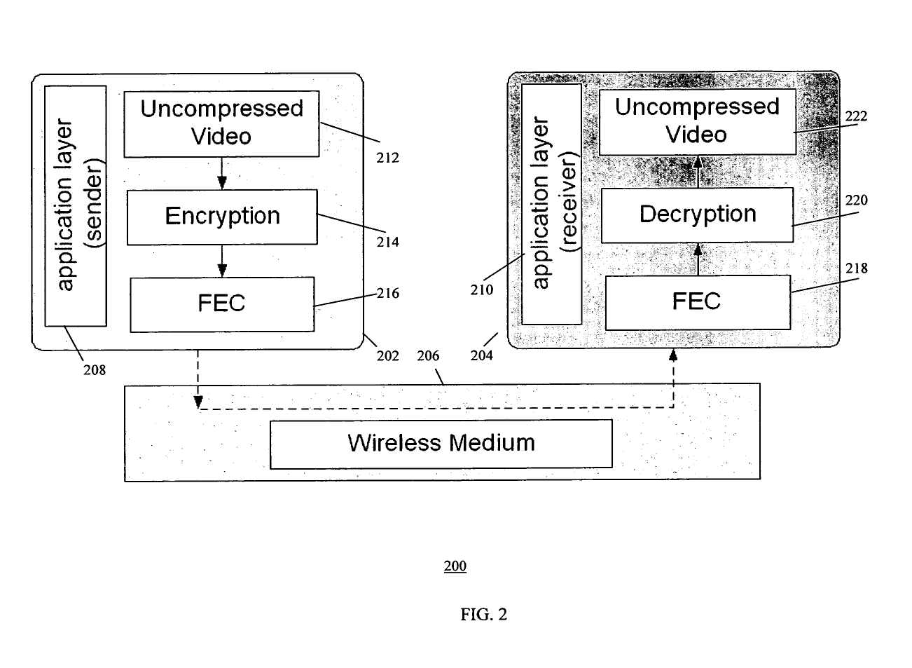

FIG. 2 shows a block diagram of an example communication system 200 implementing encryption and FEC, according to an embodiment of the present invention. The system 200 includes a sender (transmitter) 202 and a receiver 204 communicating through a wireless medium 206, such as a 60 GHz wireless channel. The sender 202 includes an application layer 208 (such as the application 100 in FIG. 1), and the receiver includes an application layer 210. The receiver application layer 210 performs the inverse process of the sender application layer 208.

The frame of uncompressed video 212 is divided into multiple scan lines. Each scan line includes an integer number of pixels, wherein each pixel includes multiple components. Quantization for pixel depth or bits per component (bit-plane) can be, for example, 8-bit, 10-bit, 12-bit, or 16-bit values.

Typically, encryption algorithms have error propagation (or multiplication) properties, wherein a single bit complement in the cipher text leads to more than one bit being affected in the corresponding plain text after the decryption process. If encryption follows FEC, this error propagation property can result in increased FEC encoding processing. FEC introduces redundancy, whereby the receiver can correct a few bits in the event of bit error loss. If encryption follows FEC, then an eavesdropper can easily exploit the redundancy.

Therefore, as shown by example in FIG. 2, the uncompressed HD video 212 is first encrypted by an encryption module 214, and then encoded by a FEC module 216. Then the data is transmitted from the sender 202 to the receiver 204 via the wireless channel 206. The receiver 204 performs inverse FEC 218 and applies decryption 220 to the received data to reconstruct the uncompressed HD video 222.

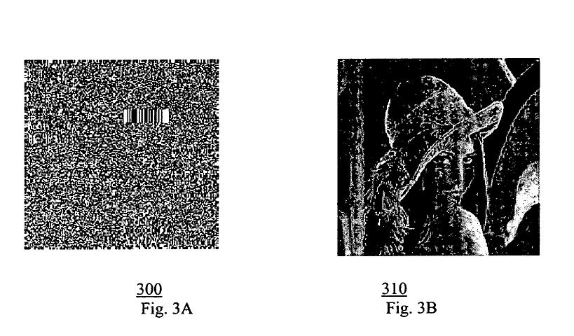

In the context of multimedia applications, encryption protects content from unauthorized copying. Since encryption schemes are computation time intensive, a trade-off between content security and computation complexity is determined. FIGS. 3A and 3B show examples of conventional selective bit-plane encryption. FIG. 3A shows an image 300, wherein encrypting the MSBs (FIG. 3A) introduces significant noise in the image. FIG. 3B shows an example image 310 wherein encrypting the 4 bits starting from the LSB, (FIG. 3B) does not degrade the image significantly. This is because an encryption algorithm introduces randomness in the input plain text (i.e., unmodified bits). If the plain text is already random, it cannot become more random.

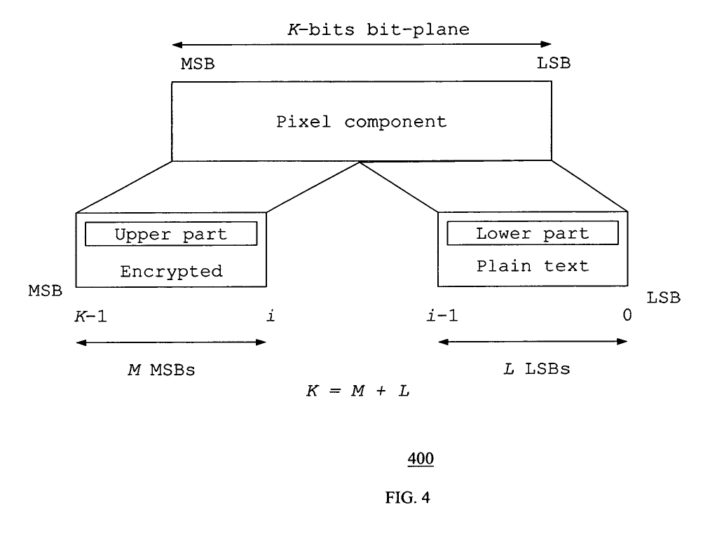

FIG. 4 diagrammatically illustrates an example of perceptual encryption of uncompressed video, according to the present invention. The bit-plane of a pixel component of K bits is partitioned into M MSBs (upper part) and L LSBs (lower part). The M MSBs are encrypted, whereas the L LSBs are left as plain text.

In one embodiment, M and L bits can be further partitioned into multiple sub-groups.

Counter-mode encryption (CTR-mode), Output feedback (OFB) encryption, Cipher Feedback (CFB) encryption, etc., are examples of a few encryption algorithms suitable for perceptual encryption. As those skilled in the art recognize, the present invention is useful with any type of block cipher.

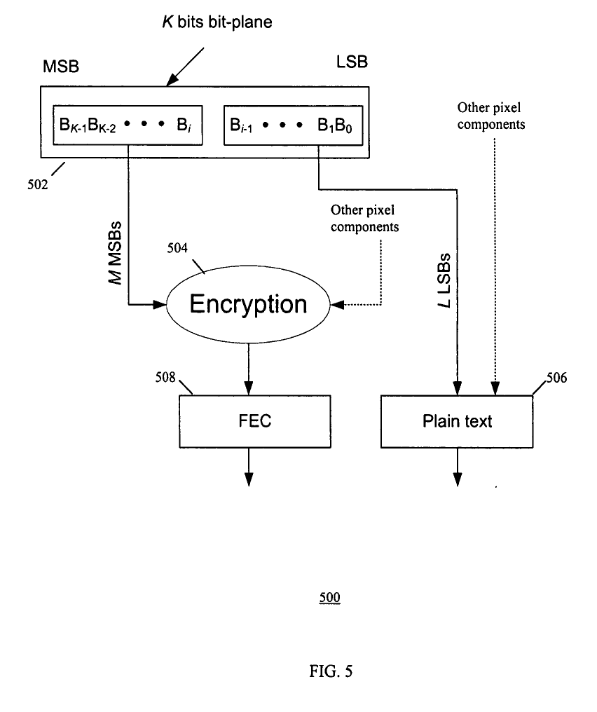

FEC is used to protect encrypted MSB bits which carry more valuable information than the plain text LSBs. FIG. 5 shows example architecture 500 for encrypting and encoding uncompressed video for wireless transmission, according to an embodiment of the present invention. The bit-plane of a pixel component 502 having K bits (K bits bit-plane), is partitioned into M MSBs and L LSBs such that K=M+L. The M MSBs (from i^{th} to K−1^{th}, where i=L) bits are encrypted by an encryption process 504, which makes the video image very noisy. Hence, the video image becomes less interesting to eavesdropping or illegal copying. The L LSBs (from 0^{th} to i−1^{th}, where i=L) bits as plain text (unmodified bits) 506, starting from the LSB, are not encrypted. Hence, the encryption computation time is reduced by L, without compromising the content confidentiality. After encryption, a FEC process 508 is performed on the encrypted bits.

In one embodiment, M and L bits can be further partitioned into multiple sub-groups. For each sub-group encryption and/or FEC is provided such that the first sub-group starting from the MSB (B_{K-1}) has the strongest encryption and FEC.

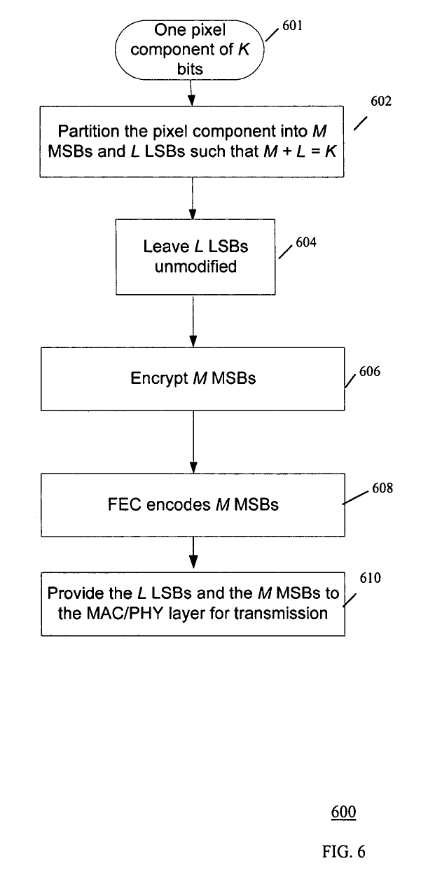

FIG. 6 shows an example flowchart a process 600 for the perceptual encryption and FEC encoding in FIG. 5, including the steps of:
Step 601: Obtain a pixel component having K bits.
Step 602: Partition the component into M MSBs and L LSBs such that M+L=K.
Step 604: Leave L LSBs unmodified.
Step 606: Encrypt M MSBs using a cipher.
Step 608: Perform FEC on the encrypted data.
Step 610: Provide the unmodified L LSBs and the encrypted and encoded M MSBs to the MAC/PHY layer of the wireless sender 202 to transmit to the receiver 204 (FIG. 2).

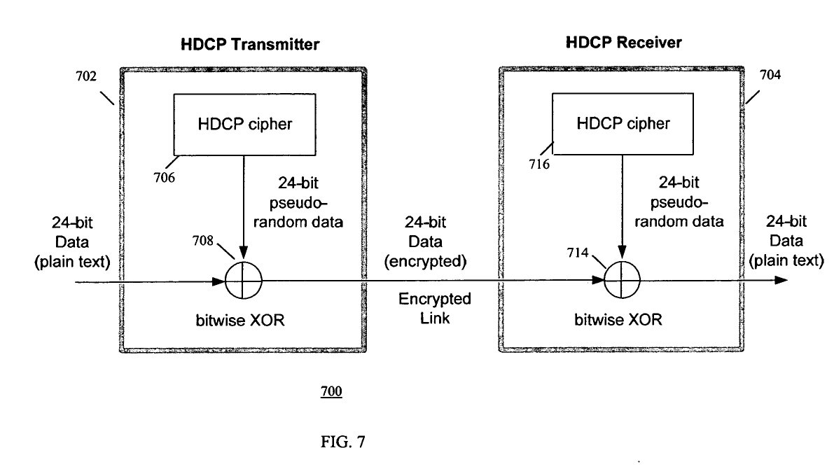

An example of perceptual encryption and FEC according to the present invention using High-bandwidth Digital Content Protection (HDCP) encryption is now described. The HDCP is designed for use with HDMI. The HDCP encryption works as a stream cipher. FIG. 7 illustrates the functioning of a conventional HDCP in a system 700 including a HDCP sender 702 (transmitter) and a HDCP receiver 704. The sender 702 includes a HDCP cipher 706 and a combination node (e.g., a bitwise XOR) 708. The receiver 704 includes a combination node 714 and a HDCP cipher 716. The input to the HDCP transmitter 702 is 24-bit data and the output is 24-bit ciphered data. The input to the HDCP receiver 704 is 24-bit ciphered data and the output is 24-bit plain (un-ciphered or de-ciphered) data. The HDCP cipher units 706 and 716 use 24-bit pseudo-random data which when bitwise XORed with 24-bit input data to the HDCP sender 702, produces 24-bit ciphered data at the HDCP sender 702, and when bitwise XORed with 24-bit ciphered data input to the HDCP receiver 704, produces 24-bit plain data at the HDCP receiver 704.

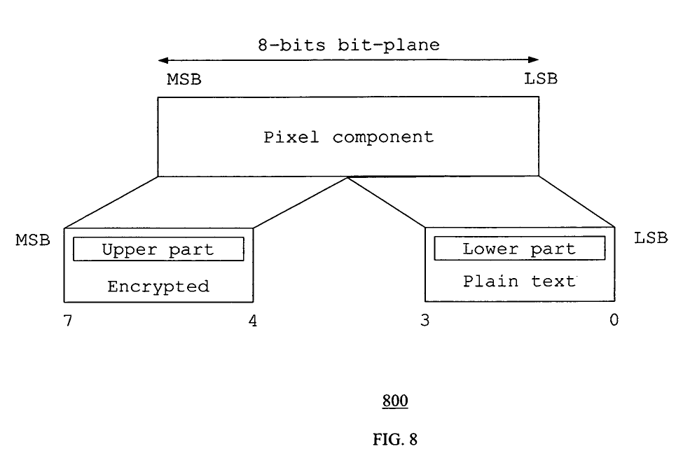

FIG. 8 shows a special case example of perceptual encryption in FIG. 4, for an 8-bit pixel component 800 wherein K=8 (i.e., 0 . . . K−1 are 8 bits) in FIG. 8, and L LSBs=4 bits and M MSBs=4 bits. The 4 MSB bits starting from the 4^{th}-bit to the 7^{th}-bit are encrypted and the other 4 LSB bits starting from bit 0 to the 3^{rd}-bit are left unmodified. As such, in this example of perceptual encryption, 50% of bits are encrypted and the other 50% of bits are left unmodified.

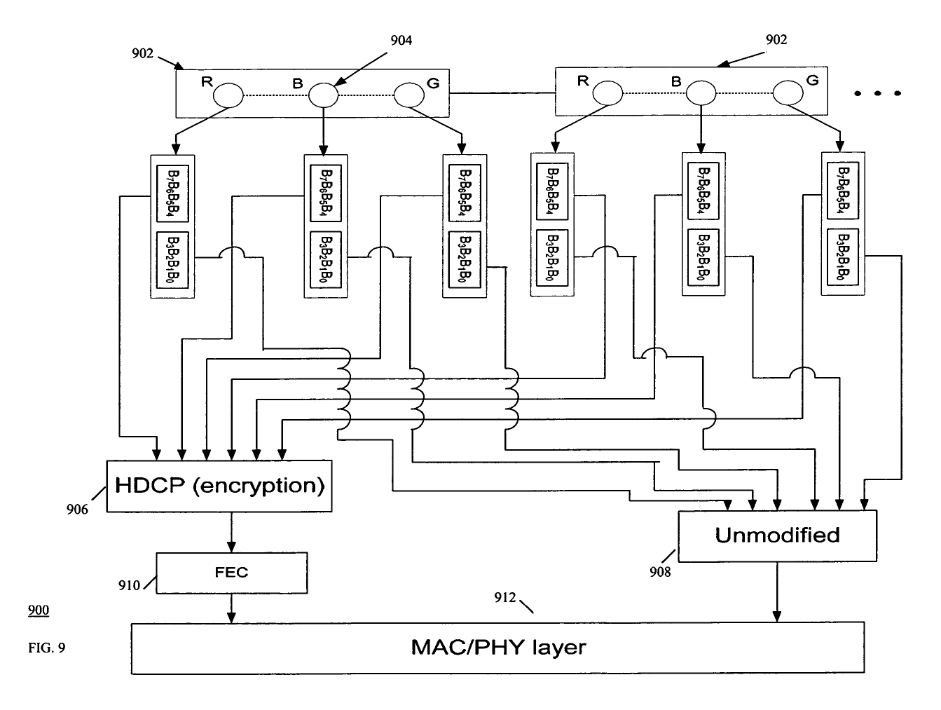

FIG. 9 illustrates an example process 900 including perceptual encryption and FEC processing, according to an embodiment of the present invention. FIG. 9 illustrates the functioning of HDCP utilizing perceptual encryption and FEC processing in a wireless sender, according to an embodiment of the present invention. Each input pixel 902 includes R (Red), B (Blue) and G (Green) components 904, and that each of the R, B and G components 904 comprises 8 bits. Half of the bits of each component 904 are encrypted by a HDCP (encryption) module 906. Each pixel 902 has 12-bits encrypted and the other 12-bits 908 remain unmodified. Thus, two 12-bit MSBs from the two pixels 902 are encrypted using HDCP encryption, while the 12-bit LSBs of the two pixels 902 remain unmodified.

The two 12-bit MSBs from the two pixels 902 are provided to the HDCP module 906 as a 24-bit input for encryption. The encrypted output bits from the HDCP module 906 are then encoded by a FEC encoding module 910 to provide transmission error recovery for the bits at the receiver. This reduces encryption computation time by half without compromising the confidentiality of underlying uncompressed video stream. The encrypted and encoded bits, along with unmodified bits, are then provided to the MAC/PHY layer 912 of the sender for wireless transmission to a receiver. The receiver then performs the reverse steps of the sender to reconstruct the video pixels.

As is known to those skilled in the art, the aforementioned example architectures described above, according to the present invention, can be implemented in many ways, such as program instructions for execution by a processor, as logic circuits, as an application specific integrated circuit, as firmware, etc.

The present invention has been described in considerable detail with reference to certain preferred versions thereof; however, other versions are possible. Therefore, the spirit and scope of the appended claims should not be limited to the description of the preferred versions contained herein.

What is claimed is:

1. A method of communicating video information over a communication medium, comprising the steps of:
inputting video information including video pixels;
for each video pixel, encrypting at least one portion of the pixel information to generate encrypted data, and encoding the encrypted data for transmission error recovery; and
transmitting the encrypted and encoded data along with the remaining portion of the pixel information, over the communication medium.

2. The method of claim 1 wherein:
encrypting at least one portion of the pixel information further includes performing perceptual encryption on said at least one portion of the pixel information; and
encoding the encrypted data further includes performing forward error correction (FEC) on the encrypted data.

3. The method of claim 2 wherein:
each pixel comprises multiple components;
the method further comprises partitioning the bit-plane of a component having K bits into M MSBs and L LSBs, wherein K=L+M; and
the step of encrypting further includes encrypting the M MSBs to generate encrypted data.

4. The method of claim 3 wherein:
the L LSBs represent said remaining pixel component information; and
the step of transmitting includes transmitting the encrypted and encoded M MSBs along with the L LSBs.

5. The method of claim 4 wherein encrypting the M MSBs further includes encrypting only the M MSBs, from i^{th} to K−1^{th} bits, where i=L, to generate encrypted data, such that the L LSBs, from 0^{th} to i−1^{th} bits, where i=L, starting from the LSB, are unmodified.

6. The method of claim 1 wherein the video information comprises uncompressed video and the communication medium comprises a wireless channel.

7. The method of claim 1 further comprising the steps of:
receiving the transmitted pixel data including the encrypted and encoded portion of the pixel, along with the remaining unmodified portion of the pixel information;
using FEC information to recover any transmission errors in the encrypted data portion;
decrypting the encrypted data portion; and
reconstructing the uncompressed video pixel based on the decrypted data portion and said unmodified portion.

8. The method of claim 3 wherein the step of encrypting further includes performing cipher.

9. The method of claim 8 wherein:
the step of performing cipher further includes performing HDCP cipher on a portion of the pixel information to generate ciphered data; and
the step of transmitting further includes transmitting the ciphered data along with said unmodified remaining portion of the pixel information.

10. The method of claim 9 further comprising the steps of:
receiving the transmitted pixel data including the ciphered and encoded portion of the pixel, along with the unmodified portion of the pixel;
using FEC information to recover transmission errors in the ciphered data;
deciphering the ciphered data portion; and
combining the deciphered data portion with the unmodified portion to regenerate the uncompressed video pixel.

11. The method of claim 3 wherein:
each pixel comprises three components, each component including K bits;
the step of partitioning further includes partitioning the bit-plane of each component into M MSBs and L LSBs, wherein K=L+M; and
the step of encrypting further includes encrypting the M MSBs from each component to generate encrypted data.

12. The method of claim 11 wherein:
the step of encrypting further includes performing HDCP encryption on the M MSBs of each pixel component; and
the step of encoding further comprises performing FEC coding on the encrypted M MSBs of each pixel component.

13. The method of claim 12 wherein the step of transmitting further includes transmitting the encrypted and encoded M MSBs of each pixel component along with unmodified L LSBs of each pixel component.

14. The method of claim 13 wherein:
the uncompressed video comprises 24-bit input pixel data, such that each pixel component comprises 8-bits;
the step of partitioning further includes partitioning the bit-plane of each component into 4 MSBs and 4 LSBS;
the step of encrypting further includes performing HDCP encryption on the 4 MSBs from each component to generate encrypted data;
the step of encoding further comprises performing FEC coding on the encrypted 4 MSBs of each pixel component; and
the step of transmitting further includes transmitting the encrypted and encoded 4 MSBs of each pixel component along with unmodified 4 LSBs of each pixel component.

15. A video information communication system, comprising:
a wireless transmitter configured to transmit video pixel information over a communication medium to a wireless receiver;
the wireless transmitter including:
an encryption module that is configured to encrypt at least one portion of video pixel information to generate encrypted data;
an encoder that is configured to encode the encrypted data for transmission error recovery; and
a transmission module that is configured to transmit the encrypted and encoded data along with the unmodified remaining portion of the pixel information, over the communication medium to the receiver.

16. The system of claim 15 wherein:
the encryption module performs perceptual encryption; and
the encoder performs FEC encoding.

17. The system of claim 16 wherein:
each pixel comprises multiple components, each component including K bits;
the system further comprises an application module that partitions the bit-plane of a pixel component into M MSBs and L LSBS, wherein K=L+M; and
the encryption module is further configured to encrypt the M MSBs to generate encrypted data.

18. The system of claim 17 wherein:
the L LSBs represent said remaining pixel component information; and
the transmission module is further configured to transmit the encrypted and encoded M MSBs along with the L LSBs.

19. The system of claim 16 wherein the encryption module is further configured to encrypt only the M MSBs, from i^{th} to K−1^{th} bits, where i=L, to generate encrypted data, such that the L LSBs, from 0^{th} to i−1^{th} bits, where i=L, starting from the LSB, are unmodified.

20. The system of claim 15 wherein:
the video information comprises uncompressed video high definition video; and
the communication medium comprises a wireless channel.

21. The system of claim 15 wherein the receiver includes:
a receiving module that is configured to receive the transmitted pixel data including the encrypted and encoded portion of the pixel, along with the unmodified portion of the pixel;
a FEC module that is configured to perform FEC on erroneous received data to obtain encrypted data; and
a decryption module that is configured to decrypt the encrypted data portion;
wherein the decrypted data portion along with the unmodified portion form the video pixel.

22. The system of claim 17 wherein the encryption module is further configured to perform cipher.

23. The system of claim 22 wherein:
the encryption module is further configured to perform HDCP cipher on a portion of the pixel information to generate ciphered data; and
the transmission module is further configured to transmit the ciphered data along with said unmodified remaining portion of the pixel information.

24. The system of claim 23 wherein the receiver includes:
a receiving module that receives the transmitted pixel data including the ciphered and encoded portion of the pixel, along with the unmodified portion of the pixel;
a FEC module that is configured to perform FEC on erroneous received data to recover transmission errors in the ciphered data; and
a deciphering module that is configured to decipher the ciphered data portion;
wherein the deciphered data portion along with the unmodified portion form the video pixel.

25. A transmitter for transmitting video information over a communication medium, comprising:
an encryption module that is configured to encrypt at least one portion of a video pixel information to generate encrypted data;
an encoder that is configured to encode the encrypted data for transmission error recovery; and
a transmission module that is configured to transmit the encrypted and encoded data along with the unmodified remaining potion of the pixel information, over a communication medium to a receiver.

26. The transmitter of claim 25 wherein:
the encryption module performs perceptual encryption; and
the encoder performs FEC encoding.

27. The transmitter of claim 26 wherein:
each pixel comprises multiple components, each component including K bits;
the transmitter further comprises an application module that partitions the bit-plane of a pixel component into M MSBs and L LSBs, wherein K=L+M; and
the encryption module is further configured to encrypt the M MSBs to generate encrypted data.

28. The transmitter of claim 27 wherein:
the L LSBs represent said remaining pixel component information; and
the transmission module is further configured to transmit the encrypted and encoded M MSBs along with the L LSBs.

29. The transmitter of claim 26 wherein the encryption module is further configured to encrypt only the M MSBs, from i^{th} to K−1^{th} bits, where i=L, to generate encrypted data, such that the L LSBs, from 0^{th} to i−1^{th} bits, where i=L, starting from the LSB, are unmodified.

30. The transmitter of claim 25 wherein:
the video information comprises uncompressed video high definition video; and
the communication medium comprises a wireless channel.

31. The transmitter of claim 25 wherein:
the encryption module is further configured to perform HDCP cipher on a portion of the pixel information to generate ciphered data; and
the transmission module is further configured to transmit the ciphered data along with said unmodified remaining portion of the pixel information.

32. A receiver for receiving video information over a communication medium, comprising:
a receiving module that receives transmitted pixel data including an encrypted and encoded portion of the pixel information, along with an unmodified portion of the pixel information;
a recovery module that is configured to recover erroneous received data to obtain the encrypted data; and
a decryption module that is configured to decrypt the encrypted data portion;
wherein the decrypted data portion along with the unmodified portion form the video pixel.

33. The receiver of claim 32 wherein:
the recovery module is further configured to perform FEC to recover erroneous received data to obtain the encrypted data.

34. The receiver of claim 33 wherein:
a receiving module is further configured to receive transmitted pixel data including the ciphered and encoded portion of the pixel, along with the unmodified portion of the pixel;
the error recovery module is further configured to perform transmission error recovery to recover transmission errors in the ciphered data; and
the decryption module comprises a deciphering module that is configured to decipher the ciphered data portion;
wherein the deciphered data portion along with the unmodified portion form the video pixel.

35. A method of communicating video information over a communication medium, comprising the steps of:
inputting video information including video pixels;
for each video pixel, encrypting at least one portion of the pixel information with stronger encryption to generate encrypted data, and encoding the encrypted data with stronger codes for transmission error recovery;
encrypting the remaining portion of the pixel with relatively weaker encryption to generate encrypted data;
encoding the encrypted data with relatively weaker code for transmission error recovery; and
transmitting the stronger encrypted and encoded data along with weaker encrypted and encoded data, over the communication medium.

36. The method of claim 35 wherein encryption and encoding of the remaining portion of the pixel includes a pass through operation.

37. The method of claim 35 wherein encrypting a portion of pixel includes partitioning the pixel data into multiple sub-groups, and for each sub-group provide encryption and forward error correction (FEC) on the encrypted data.

38. The method of claim 37 wherein:
the sub-group starting from the MSB is provided with the strongest encryption and forward error correction (FEC).
